(19) United States
(12) Patent Application Publication
(10) Pub. No.: US 2011/0157893 A1
(43) Pub. Date: Jun. 30, 2011

(54) OLED LUMINAIRE HAVING OBSERVABLE SURFACES WITH DIFFERENTIAL VISUAL EFFECTS

(76) Inventors: Peter Y.Y. Ngai, Alamo, CA (US); Naomi Miller, Portland, OR (US)

(21) Appl. No.: 12/648,277

(22) Filed: Dec. 28, 2009

(51) Int. Cl. F21V 21/00; F21K 99/00

(52) U.S. Cl. 362/249.02; 362/382

(57) ABSTRACT

An OLED luminaire has at least one panel structure having a generally planar observable surface and at least one OLED panel having a light emitting surface forming at least a portion of the panel structure and having a sufficiently high lumen output for illuminating a space. The generally planer observable surface of the panel structure, including the light emitting surface of said OLED panel, create visual interest by exhibiting differential visual effects, such as different low luminance patterns or different color patterns, or both, when the OLED panel or panels are driven to a state of illumination. Differential visual effect on the luminaire's panel structure can also be created by the juxtaposition of illuminated OLED panels and non-illuminated fill panels.

### FIELD OF INVENTION

The present invention generally relates to luminaires for illuminating a space, and more particularly to luminaires using organic light emitting diodes (OLEDs) as a light source.

### BACKGROUND

An OLED provides a highly efficient and controllable source of light that has found application in high resolution displays ranging from small screen displays for mobile telephones and the like to displays for flat screen televisions currently up to about 15 inches. Relatively complex drive circuits are required to drive each of the tiny display pixels of these displays with the objective of producing a sharp and visible image on the screen. Such displays are not intended to illuminate a space. Indeed, the overall light output of such displays is relatively low as compared to the light output needs for general lighting.

OLEDs have been considered as a possible light source for general lighting applications but have not yet resulted in a commercially available luminaire for general lighting. Heretofore, design approaches to possible OLED based luminaires have involved treating the OLED like conventional like sources (e.g. incandescent bulbs, fluorescent lamps, and CFLs), that is, as a source of light only. With such approaches, the objective is to drive the OLED so that the light emitting surface of the OLED produces enough light to illuminate a space. To do so the OLEDs are driven to achieve a constant luminance over the OLED's entire light emitting surface, without regard to the visual effects the OLED surfaces presents to an observer. Compared to conventional light sources, OLEDs can have light emitting surfaces that extend over a relatively large area in a generally planar geometry. These surfaces can be exposed to persons in the vicinity of a luminaire who will view the OLED directly. When view directly, the constant luminance of the OLED surfaces will lack visual interest and can result in luminaires having little aesthetic appeal.

The present invention provides a luminaire having one or more OLEDs light sources, which produce differential visual effects on the luminaire and which enhance the visual interest of the luminaire when seen by an observer. The enhanced visual characteristics are created on planar surfaces of the luminaire that include the OLED light sources and are created with light output from the light emitting surfaces of the OLED sources that is sufficient to illuminate a space. The planar surfaces on which the differential visual effects are created can be flat planes or curved planes, and can be a configuration of two or more planes each of which has one or more OLEDs with light emitting surfaces.

### DESCRIPTION OF THE DRAWINGS

FIG. 1 is a graphical representation of an OLED panel showing the construction thereof, and also showing driver for the OLED panel.

FIG. 2 is a graphical representation of a conventional constant luminance OLED luminaire and a driver therefore.

FIG. 3 is a graphical representation of a conventional constant luminance OLED luminaire and a driver therefore, wherein the driver is connected to bus lines of the OLED panel.

FIG. 4 is a graphical representation of an exemplary OLED luminaire in accordance with the invention and a driver and electronic controller therefore, wherein visual interest is created on an observable surface of the luminaire by producing a low resolution light pattern on the OLED panel comprised of areas of different luminance.

FIG. 5 is a graphical representation of another exemplary OLED luminaire in accordance with the invention and a driver and electronic controller therefore, wherein visual interest is created on an observable surface of the luminaire by producing a low resolution light pattern on the OLED panel comprised of areas of different color.

FIG. 6A is a graphical representation of a panel structure of an OLED luminaire containing an OLED panel and showing an exemplary light pattern thereon.

FIG. 6B is a graphical representation of a panel structure of an OLED luminaire containing an OLED panel showing another exemplary light pattern thereon.

FIG. 7 is a graphical representation of an OLED luminaire containing an OLED panel showing a light pattern thereon in the form of discreet points of light.

FIG. 8 is a graphical representation of a panel structure of an OLED luminaire containing an OLED panel showing a light pattern thereon, which includes discreet points of light.

FIG. 9 is a graphical representation of a panel structure of an OLED luminaire containing an OLED panel showing a light pattern thereon produced by an illuminated OLED panel and a surrounding unilluminated fill panel portion.

FIG. 10 is a graphical representation of a panel structure of an OLED luminaire containing an OLED panel showing a light pattern thereon produced by an illuminated OLED panel and a surrounding unilluminated and transparent fill panel portion giving the appearance of a floating light source.

FIG. 11 is a cross-sectional view of a ceiling mounted luminaire having a low profile support structure for an OLED containing panel structure wherein the OLED panel of the panel structure produces differential visual effects thereon in the form of a low resolution light pattern and a sufficient light output to illuminate a space.

FIG. 12 is a bottom perspective view of a ceiling suspended luminaire having a support structure for multiple OLED containing panel structures wherein the OLED panels of the panel structures produce differential visual effects thereon and a sufficient light output to illuminate a space.

### DESCRIPTION OF THE ILLUSTRATED EMBODIMENT

The present invention is directed to a luminaire using one or more organic light-emitting diodes (OLEDs) as the light source for the luminaire. The luminaire has at least one panel structure having a generally planar observable surface, with at least a portion of the panel structure including one or more OLED panels having light emitting surfaces that emit a sufficient amount of light to illuminate a space when the OLED panels are driven to a state of illumination. To illuminate a space the luminaires used in the space need to produce enough light within the space. For example, 50 footcandles is usually considered a suitable amount of light for many general lighting environments. To produce this amount of light within a space will require that the lumen output density of the luminaires used to illuminate the space be high enough to generate the needed light. For most applications, the light emitted by the OLED panel or panels of luminaires in accordance with the invention will produce a lumen output density of at least approximately 6000 lumens per square meter; however, it is contemplated that, in some applications, for example where ceiling mounted luminaires cover a high percentage of the ceiling area of a room, OLED panels having a lower lumen output density could be used, provided the total lumen output of the luminaires for the particular application is sufficient to illuminate the space.

As described in greater detail below, when the luminaire is turned on, the observable planar surface of the panel structure will, in addition to producing enough light to illuminate a space, exhibit observable differential visual effects for producing visual interest. The differential visual effects on the planar surface of the panel structure can include light patterns created by different light emitting areas or by effects created by a light emitting area next to a non-light emitting area.

It will be understood that the generally planar observable surface of the panel structure of a luminaire in accordance with the invention, including the OLED panel, is not limited to a flat plane, but can be a surface that lies in a curved plane.

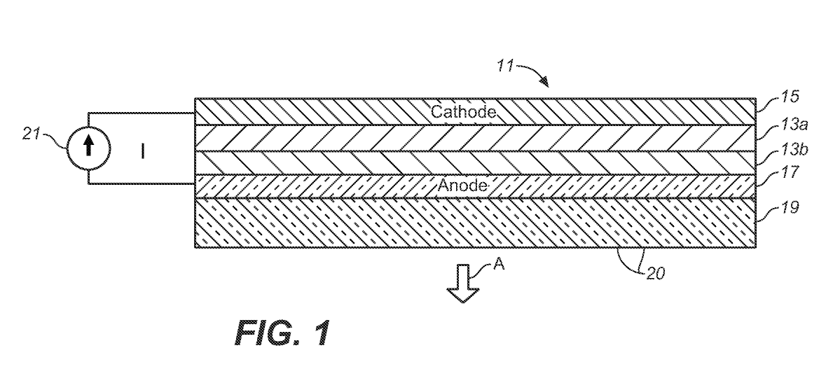

The basic construction of an OLED panel is described with reference to FIG. 1 of the drawings. Referring to FIG. 1, the OLED panel 11 has layers of organic, electroluminescent material 13a, 13b sandwiched between a cathode 15 and a transparent anode 17. These layers are supported on a substrate 19 that is also transparent, typically glass or a flexible, clear plastic. A backing (not shown) can be provided at the back of the OLED panel behind the cathode 15.

The layers of organic electroluminescent material are made up of an emissive layer 13a and a conductive layer 13b. When a sufficient voltage is applied between the cathode and the anode of the OLED, the cathode gives up electrons to the emissive layer and the anode draws electrons from the conductive layer, leaving positively charged “holes” in the conductive layer. A surplus of electrons in the emissive layer attract the more mobile positively charged holes in the conductive layer toward the emissive layer, where the electrons and holes combine to cause a drop in the energy levels of the electrons. This recombining of electrons and holes causes radiation in the form of light, which is emitted from the emissive layer through the transparent anode and OLED substrate. This light emerges from the bottom light emitting surface of the OLED substrate, as indicated by the arrow “A” shown in FIG. 1. It is noted that the OLED is a current controlled device driven by a constant current source connected across the OLEDs anode and cathode as denoted by the current source driver 21.

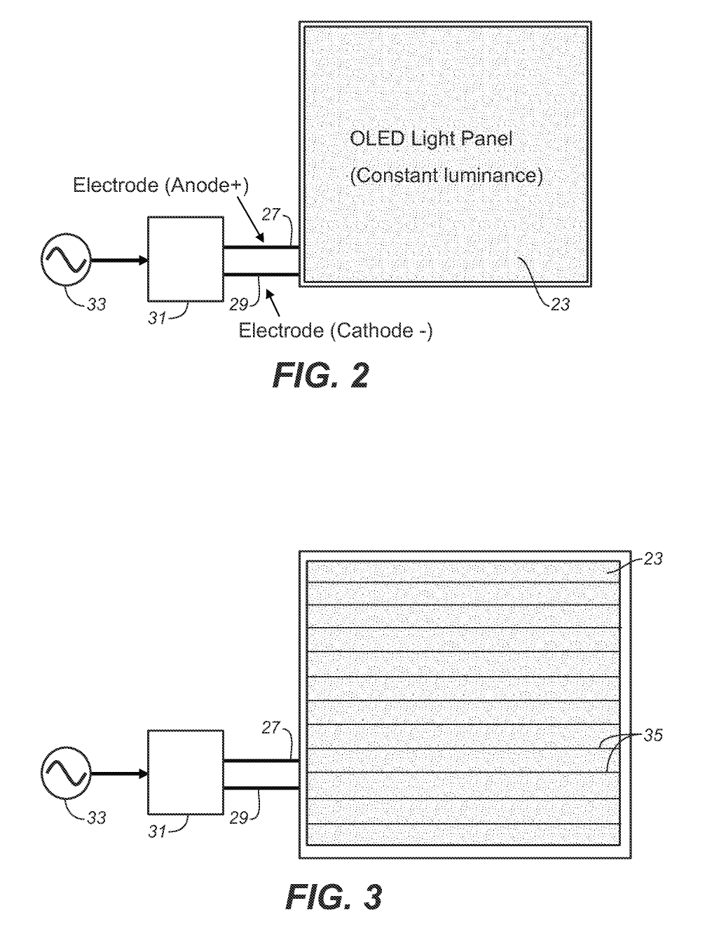

FIGS. 2 and 3 graphically illustrate a basic OLED light panel and OLED drive configuration that can be used as an OLED light source for a luminaire. In FIG. 2, the OLED light panel 23 of the luminaire has a positive electrode 27 (the anode) and a negative electrode 29 (the cathode). These electrodes are connected to an electrical driver 31 having an AC input 33. Driver 31 converts the AC input to a constant current source for driving the OLED panel to a state of illumination. FIG. 3 shows a variation of the luminaire graphically depicted in FIG. 2, wherein the electrical driver 31 having an AC input 33 is connected to multiple bus lines 35 running through the OLED panel.

In each of the basic OLED configurations shown in FIGS. 2 and 3, the OLED light panel is depicted as a single pixel, that is, as a single addressable portion of the OLED that can be driven to a state of illumination. In each case the entire panel is illuminated and produces a constant luminance across the entirety of the OLED's observable planar surface without a discernable pattern of light on the surface. The OLED source is intended to produce light to illuminate a space in the vicinity of the luminaire. By itself, it does not create differential visual effects that would provide an OLED luminaire with visual interest.

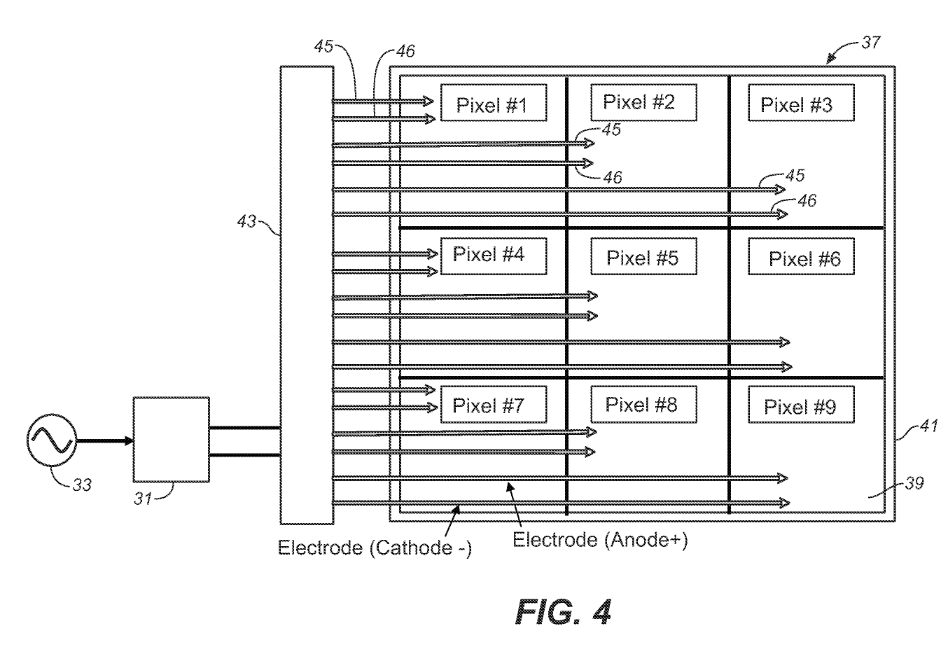

FIG. 4 graphically illustrates a luminaire having an OLED light source, which not only functions as a source of light for illuminating a space, but in accordance with the invention also produces a source of visual interest on the luminaire, and particularly on the planar portion of the luminaire in which the OLED light source appears. In FIG. 4, the light source for the luminaire is an OLED panel having multiple addressable pixels that are driven to different states of illumination, so as to produce an observable low resolution light pattern on the observed planar surface of the OLED panel.

Referring to FIG. 4, the graphically represented luminaire is denoted by the numeral 37 and the OLED panel by the numeral 39. A support structure for the OLED panel is represented by an outer perimeter frame 41. The addressable pixels of the OLED panel are pixels numbered 1 through 9, and are arranged in a 3×3 square grid pattern such that patterns of light can be produced on the light emitting surface of the OLED panel when the different pixels of the OLED panel are driven to different states of illumination.

FIG. 4 also shows an electrical input for driving the OLED panel 39 to a state of illumination, and more specifically for driving the different pixels of the OLED panel. The electrical input for the OLED panel is provided by driver 31 and electronic controller 43. Driver 31 converts an externally supplied AC input 33 to a constant current source suitable for driving a current controlled OLED device. The output of the driver is connected to the electronic controller, which controls the amount of current delivered to each of the OLED's addressable pixels. By controlling the current to each pixel the controller can control the light output from each pixel and thus the luminance of the observed lighting emitting surface of the OLED panel at each pixel. The light-emitting surface of the OLED panel at one pixel can be made to exhibit a luminance that is different from the luminance at an adjacent pixel. One or more pixels could also be “turn off” causing the OLED surface to exhibit an unilluminated area next to an illuminated area. The illuminated pixels will collectively have sufficient light output to illuminate a space, such as a room or passageway. At the same time, the difference in luminance among the pixels will create an observable pattern of light on the observed surface of the OLED panel.

In accordance with the invention, the separately addressable pixels of the OLED panel are provided in relatively large-dimensioned pixels for producing a low-resolution light pattern having visual interest to the observer. For example, nine addressable 6 inch×6 inch square pixels can suitably be provided in an 18 inch square OLED panel to produce a very low-resolution light pattern configured from the 6 inch squares. More refined, yet still low-resolution light patterns can be created by using smaller pixel sizes. For example, an 18 inch×18 inch square OLED panel divided into 2 inch×2 inch square pixels would provide a grid of 81 addressable pixels from which to create an observable pattern of light. Again, at their different states of illumination, the pixels will produce sufficient light output to illuminate a space.

In the configuration shown in FIG. 4, it is seen that nine cathode-anode electrode pairs are provided for each of the nine OLED pixels. The luminance of each pixel is controlled by the drive current through the electrode pairs to each pixel, as determined by the controller 43. The outputs of the controller are connected to the cathode and anode electrode pairs 45, 46 for each pixel and allow each pixel to be directly driven to a desired state of illumination. The controller can be readily implemented by known circuit designs, and can be provided with variable controls (not shown) for allowing adjustment to the pixel drive for changing light patterns on the OLED panel. Means can also be provided for remotely adjusting the pixel drives for remote adjustment of observable surface patterns on the luminaire, or drives that are time-varying for a time-varying surface pattern.

It will be understood that the square perimeter shape of the OLED panel 39 and the square shape of the OLED pixels 1-9 illustrated in FIG. 4 are representative only, and that the OLED panel and OLED pixels could be provided in other shapes, such as rectangular shapes, circular shapes, and oval shapes.

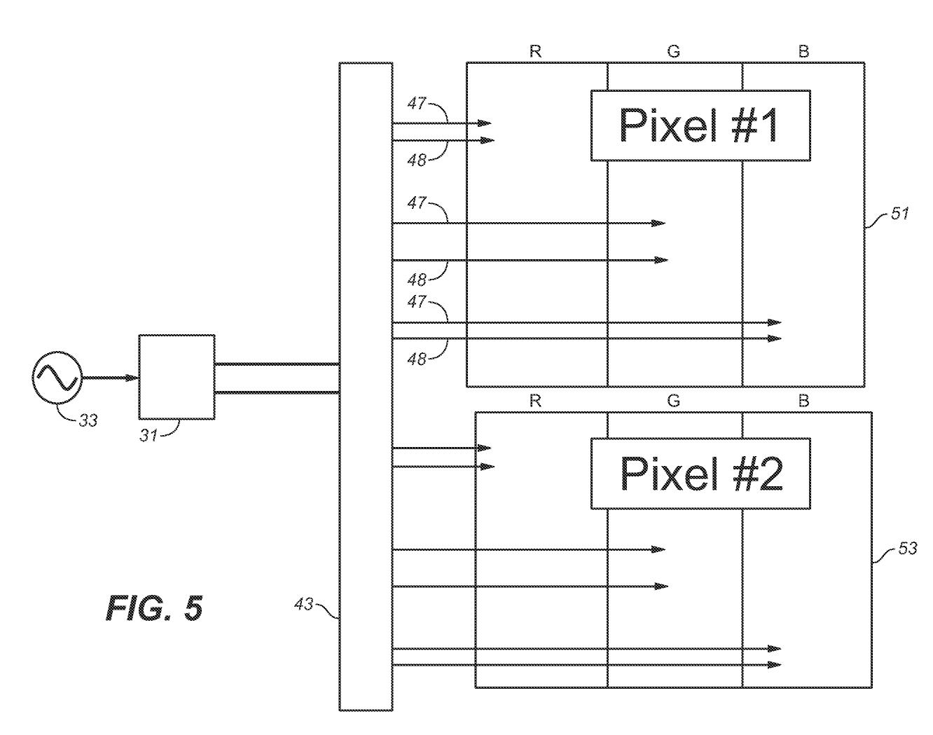

FIG. 5 graphically illustrates to provide a light pattern on the light-emitting surface of an OLED panel of a luminaire comprised of color patterns instead of, or in addition to, patterns of different luminance. In FIG. 5 the illustrative OLED panel is made up of two large pixels 51, 53 connected to driver 31 with an AC input 33 through electronic controller 43. In this case, the controller drives the red (R), green (G), and blue (B) components of each pixel to a different intensity to produce light from the pixel having a desired color. Thus, by adjusting the current drives to the RGB components of each pixel, color contrast can be produced between pixel 51 and 53. Such color contrasts can be combined with driving the pixels of the OLED panel to different luminance levels to produce lighting patterns on the light emitting surface of the OLED panel that vary in both color and luminance.

Different visual effects can be provided on the observable light emitting surface of the OLED panel by means other than driving addressable pixels of an OLED panel to different states of illumination, as above-described. Another approach to achieving differential effects is to configure two or more contiguous OLED panels together in a support structure, and to create a low resolution light pattern by driving the different OLED panels to different states of illumination, for example, to different luminance levels and different colors, or both. Yet another approach, an example of which is hereinafter described in greater detail, is to drive a single OLED panel or multiple panels to the same state of illumination, and to surround or intersperse these OLED panels with fill panels that are not sources of light, or with masked areas, whereby a low-resolution pattern on an observable planar surface of the luminaire is produced, at least in part, by non-light emitting surfaces next to light emitting surfaces.

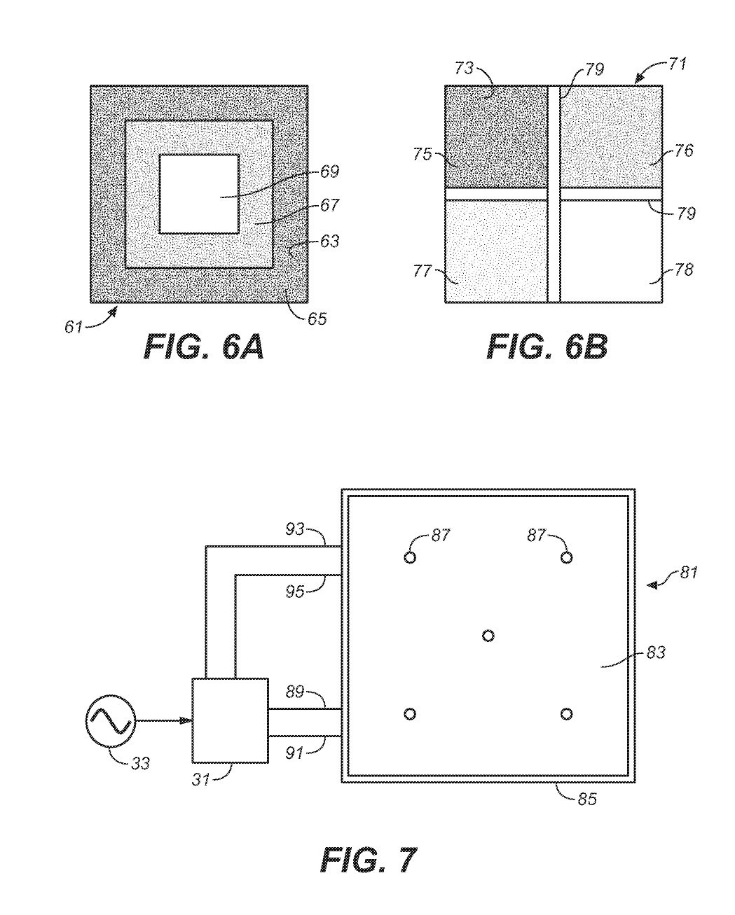

FIGS. 6A and 6B illustrate examples of the types of surface patterns that can be produced on the planar observable surface of a panel structure of a luminaire having one or more OLED panels driven to different states of illumination, or having an OLED panel with addressable pixels driven to different states of illumination. In FIG. 6A, a panel structure 61 is shown having a generally planar observable surface 63, on which the low-resolution pattern of light consists of an outer ring 65, an intermediate ring 67, and inner square 69. This pattern can be produced on a single OLED panel having a suitable number of addressable square or rectangular pixels for generating the pattern shown. The outer ring 65 would be produced by driving all of the outer pixels making up this ring to the same state of illumination, for example, a state of illumination wherein the luminance is high and the color is red. Similarly, the inner ring 67 would be generated by driving the pixels corresponding to this ring to a different state of illumination, such as a level of luminance lower than the level of luminance of the outer ring, and a different color, such as green. The center square 69 could be unilluminated, and could consist of a non-OLED fill panel, or could be part of the OLED that is driven to a different state that creates a different luminance level and/or color at this square, for example a very low luminance as compared to the outer and intermediate rings 65, 67, and where the color is blue. Thus, transitions from outer area of high luminance to center areas of relatively low luminance can be produced, and by increasing the number of rings the transitions can be made to be more gradual.

Another example of an observable low-resolution light pattern that can be produced on the panel structure of the luminaire is shown in 6B. In this figure, a panel structure 71 having a planar observable surface 73 has a pattern of four squares having light-emitting surfaces 75, 76, 77, 78 arranged in a block and separated by visually discernable stripes 79. The light-emitting surfaces of the square blocks and the separating stripes produce a distinctive and observable block-style light pattern. The separating strips 79 can be non-OLED masking strips, or could be an illuminated or non-illuminated area of the panel. The light pattern can be produced by driving addressable pixels of a single OLED panel to different states of illumination, or by driving separate contiguous OLED panels to different states of illumination.

The patterns shown in FIGS. 6A and 6B are exemplary only, it being understood that a wide variety of low resolution patterns that could be created on the planar observable surface of a luminaire's panel structure, which incorporate one or more OLED panels as light sources. In each case the OLED panel or panels would create visual interest while having enough light output to illuminate the space in which the luminaire is suspended or mounted.

FIG. 7 graphically illustrates a luminaire having an OLED panel as a light source with yet another differential visual effect on the light-emitting surface thereof. In this case, luminaire 81, having OLED panel 83 supported within a frame support structure 85 has relatively small “points” of light 87 embedded within the OLED panel. These points of light can be produced by separate light sources, such as conventional light emitting diodes (LEDs), embedded in the OLED panel. Driver 31, which converts the AC electrical input 30 to a constant current output, drive the OLED panel 83 to a state of illumination through electrode pair 89, 91, while at the same time driving the embedded LEDs 87 through a separate electrode pair 93, 95.

It will be understood that the “points” of light shown in FIG. 7 could be provided by separate embedded OLEDs, or by addressable pixels within a single OLED. The points of light 87 are suitably of a relatively high luminance as compared with the luminance of the light-emitting surface of the OLED panel 83. For example, the luminance of the OLED panel might be in the range of 2000 candelas per square meter while the luminance of the points of light be might over one million candelas per square meter such as can be produced by a ¼ watt LED. The small areas of high luminance will introduce a “sparkle” effect to the observed surface of the OLED.

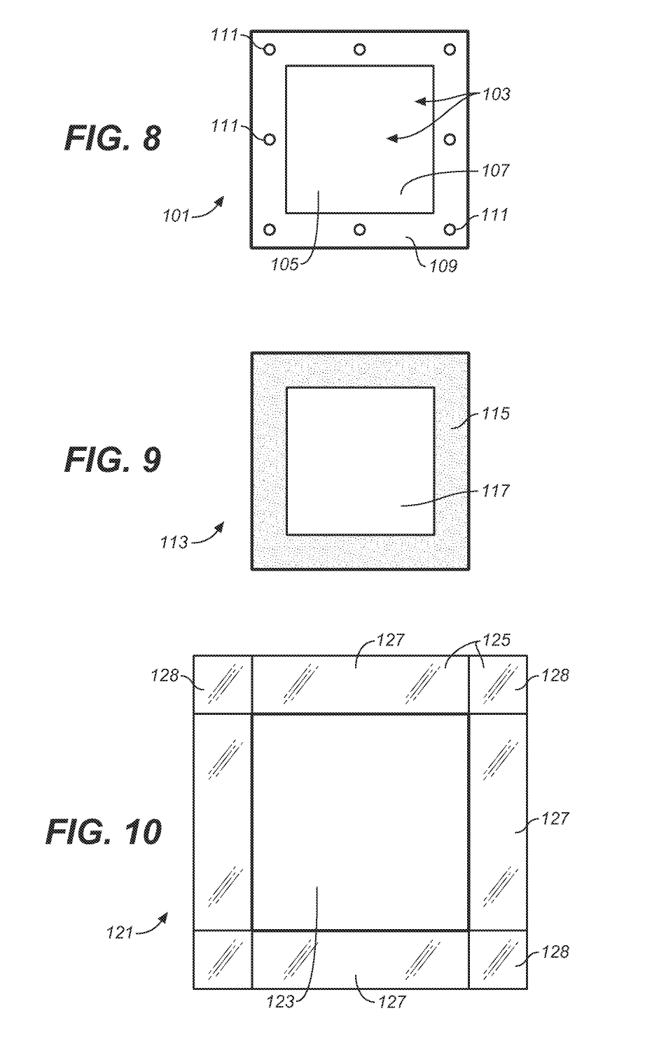

FIGS. 8 and 9 illustrate a luminaire for illuminating a space having a panel structure with a generally planar observable surface, wherein an OLED light source occupies only a portion of the planar observable surface in which the planar light source resides. In FIG. 8, the panel structure 101 has a planar observable surface 103 formed by a square OLED light source 105 having a light-emitting surface 107 and a surrounding perimeter fill panel portion 109, which is not a light-emitting surface. The fill panel portion of the panel structure 101 is provided with visual characteristics, such as a tinted surface or a white surface that contrasts with the visual characteristics of the light-emitting surface of the OLED panel. This portion of the panel structure can suitably be provided in the form of a plastic material or Plexiglas, which can be opaque, translucent, or transparent. Individual, discrete light sources 111, such as LEDs, can be provided in the fill panel portion to provide a sparkle around and outside of the OLED panel. The fill panel portion can be made up of a single piece of planar fill panel material, or of separate fill panel sections.

FIG. 9 shows a panel structure 113 similar to that shown in FIG. 8, but without the inclusion of separate, discrete light sources in the perimeter fill portion of the panel structure. In FIG. 9, the perimeter fill portion 115 that surrounds the OLED panel light source is shown as having a darker, contrasting appearance as compared to the visual appearance of the light-emitting surface of the OLED panel 117. The perimeter fill portion 115 can be provided in different colors to achieve a desired differential visual effect. The planar observable surface of the panel structure will exhibit an observable low-resolution light pattern by virtue of the contrast between the unlit fill portion 115 and the lit OLED panel 117.

FIG. 10 illustrates a panel structure for a luminaire wherein the light pattern on the panel structure is such that the light source appears to be floating in space. In FIG. 10, panel structure 121 has an interior, light-emitting OLED panel 123 surrounded by and supported within a transparent perimeter fill panel portion 125, which can suitably be configured from rectangular, clear plastic panel sections 127 and clear plastic square corner panel sections 128. When the OLED panel 123 is driven to a state of illumination, the light emitting surface of the panel will appear as a square source of light floating within a transparent border.

In any of the examples illustrated in FIGS. 8-10, the differential visual effects can be incorporated into a ceiling mounted and suspended luminaire, a wall mounted luminaire, or luminaire mounted to other structures such as poles or furniture system. In each case the OLED panel or panels and other light source elements, if any, would be driven by suitable drivers, and controllers as required, for driving the light source elements to desired states of illumination.

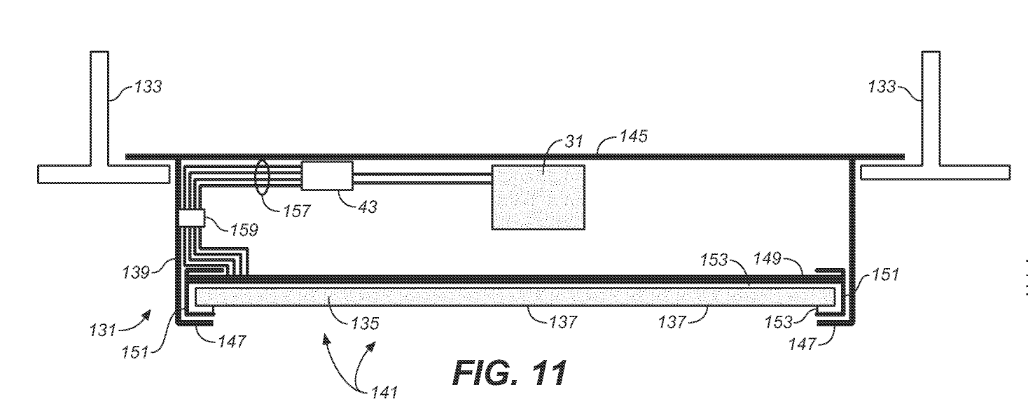

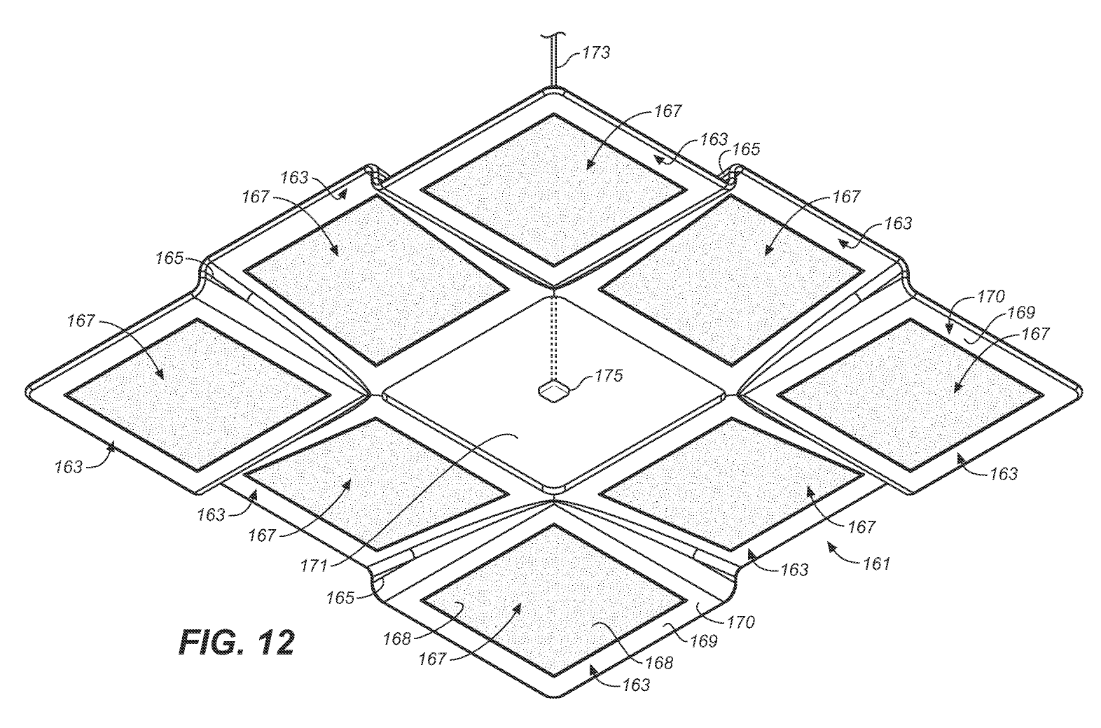

FIGS. 11 and 12 show examples of luminaires in accordance with the invention. In each case, support structures are shown for supporting the luminaire's OLED-containing panel structures for illuminating a space. In each case, the planar observable surface of the panel structure or structures, including the light-emitting surfaces of the OLED panels, will be presented to an observer located in the illuminated space, and will provide observable differential visual effects on the panel structures.

In the first example, FIG. 11 illustrates a low-profile luminaire 131 that can be supported on the T-bars 133 of a grid ceiling for illuminating the space beneath the ceiling. In this implementation, the panel structure is comprised of an OLED panel 135 having a planar observable light-emitting surface 137. The support structure for the OLED panel includes a housing 139 having a bottom opening 141 through which light from the OLED panel is emitted. The OLED panel is secured to a backing 149 and into the U-shaped perimeter frame 151 by means of a suitable sealant and adhesive 153. The backing 149 and perimeter frame 151 create a planer panel structure that can be set onto the housing's in-turned edges 147.

The housing 139 of the luminaire 131 is also seen to contain the driver 31, an electronic controller 43, and wiring for the driver and controller. The driver, which converts a high voltage AC input supplied from AC wiring in the building (not shown) to a constant current output, is connected to the electronic controller. The electronic controller is provided to directly drive different pixels of the OLED panel 135 to different states of illumination for producing a light pattern on the lighting emitting surface of the OLED panel. The electronic controller is shown as having two pairs of outputs 157 for driving two pixels of OLED panel 135. However, more outputs from the controller could be provided for driving an OLED panel having more than two pixels. The number of outputs from the electronic controller would depend on the number pixels provided by the OLED.

For ease of installation, the wiring for the luminaire shown in FIG. 11 can be provided with suitable connectors, such as the illustrated connector 159 for connecting the OLED panel 135 to the outputs of electronic controller 43.

It will be understood that, while a single OLED panel 135 is shown in FIG. 11, two or more OLED panels could be used by adhering the two or more panels to backing plate 149. The two or more panels could also be interspersed with non-OLED fill panel sections to create different visual effects, as above-described. The two or more OLED panels could be driven to different states of illumination by the outputs from the electronic controller 43, with the number of outputs depending on the number of OLED panels, or pixels in the OLED panels.

It will also be understood that the implementation of the driver and controller shown in FIG. 11 is illustrative only. The driver and controller could, for example, be provided as remote components mounted above the ceiling, and could be packaged into a single electronic package instead of being provided as separate components as shown.

FIG. 12 shows how multiple panel structures having a generally planar observable surface can be uniquely configured into a ceiling-suspended luminaire for illuminating a space. In FIG. 12, luminaire 161 is comprised of a ring of panel structures 163, which are interconnected by connecting walls 165, such that any one of the panel structures 163 is inclined at an angle from its adjacent panel structure. Each panel structure 163 has an OLED panel 167 surrounded by a perimeter fill panel portion 169, which is not illuminated. Thus, the contrast between the light-emitting surface 168 of OLED panel 167 of each panel structure provides a contrast with the observable surface 170 of the perimeter fill panel. The resulting contrast causes the panel structure to exhibit an observable low-resolution light pattern on each panel structure, with this low-resolution pattern being repeated around the ring of panel structures. The support structure for supporting the ring of OLED panel structures 163 of luminaire 161 includes a center suspension panel structure 171 connected to or integrally formed with the interior edges of the surrounding OLED panel structures. The luminaire can be suspended from the center panel structure by means of a suspension cable 173, which can be connected to the center panel by any suitable means, such as by an attachment knob 175, which screws on to a threaded connector (not shown) that is attached to the end of the suspension cable and that projects through a suitable opening in the center suspension panel. It will be appreciated that other forms of suspension could be used in the embodiment shown in FIG. 12, including a rigid suspension stem, or multiple suspensions.

Also, in the embodiment illustrated in FIG. 12, the drivers and, if required, electronic controllers for the OLED panels 167 can be supplied remotely or directly on the luminaire. For example, remote drivers can be mounted above a ceiling surface, with the drivers being wired to the OLED panels by dropping wires down along suspension cable 173 (or through a hollow stem), and through the center suspension panel 171 to the interior edges of the OLED panels. Alternatively, the drivers could be mounted to the back of the center panel structure 171 or possibly imbedded within the panel structures themselves. Remote or direct mount electronic controllers can similarly be included for driving the OLED panels, or different pixels within the same OLED panels, to different states of illumination.

It is contemplated that the each of the OLED panels of the luminaire shown in FIG. 12 can be a single pixel OLED or can have two or more pixels that can be driven to different states of illumination as above described for producing a low resolution pattern on the observable surfaces of the OLED panels. Sparkle could also be added to the panel structures 163 by adding small high luminance light sources to the panels. It is contemplated that the high luminance light sources would have a luminance of at least approximately 100,000 candelas per square meter, whereas the luminance of the light emitting surface of the OLED panel less than about 8000 candelas per square meter.

While various embodiments of the invention have been described in considerable detail in the foregoing specification, it will be understood that it is not intended that the invention be limited to the disclosed embodiments or the described details of those embodiments, except as necessitated by the following claims.

What I claim is:

1. A luminaire for illuminating a space, comprising:
at least one panel structure having a generally planar observable surface,
at least one OLED panel having a light emitting surface, said OLED panel forming at least a portion of said panel structure and having a sufficiently high lumen output for illuminating a space, the light emitting surface of said OLED panel forming at least a portion of the generally planar observable surface of said panel structure,
a support structure for supporting said panel structure such that the generally planer observable surface of said panel structure, including the light emitting surface of said OLED panel, is presented to an observer located within the space to be illuminated, and
an electrical input for said at least one OLED panel for driving said OLED panel to a state of illumination,
the generally planer observable surface of said panel structure, including the light emitting surface of said OLED panel, being characterized in that, when the OLED panel is driven to a state of illumination, the generally planar observable surface of said panel structure exhibits differential visual effects thereon.

2. The luminaire of claim 1 wherein, when the OLED panel is driven to a state of illumination, the light emitting surface of said OLED panel exhibits an observable low resolution light pattern thereon so as to create differential visual effects on the generally planar observable surface of said panel structure.

3. The luminaire of claim 2 wherein said OLED panel has at least two addressable pixels and wherein said electrical input drives said addressable pixels to two different states of illumination for producing an observable low resolution light pattern on the light emitting surface of said OLED panel.

4. The luminaire of claim 3 wherein the different states of illumination of the pixels of said OLED panel are characterized by different luminance levels, and wherein the light pattern on the light emitting surface of said OLED panel is created by said different luminance levels.

5. The luminaire of claim 3 wherein the different states of illumination of the pixels of said OLED panel are characterized by different colors of light, and wherein the light pattern on the light emitting surface of said OLED panel is created by said different colors of light.

6. The luminaire of claim 3 wherein the different states of illumination of the pixels of said OLED panel are characterized by are different luminance levels and different colors of light, and wherein the light pattern on the light emitting surface of said OLED panel is created by different luminance levels and different colors of light.

7. The luminaire of claim 1 wherein the generally planer observable surface of said panel structure, including the light emitting surface of said OLED panel, is characterized in that, when the OLED panel is driven to a state of illumination, it produces a luminance level and wherein the differential visual effects exhibited on the generally planar observable surface of said panel structure is produced at least in part by small areas of said relatively high luminance on the observable surface of said panel structure as compared to the luminance level of said OLED panel.

8. The luminaire of claim 7 wherein said small areas of high luminance are produced by high luminance light sources embedded in said panel structure.

9. The luminaire of claim 7 wherein said small areas of luminance are produced by high luminance light sources embedded in said OLED panel.

10. The luminaire of claim 7 wherein said small areas of luminance are produced by LEDs embedded in said panel structure.

11. The luminaire of claim 7 wherein said small areas of luminance are produced by LEDs embedded in said OLED panel.

12. The luminaire of claim 1 wherein the said panel structure includes at least one fill panel section that does not illuminate and which is adjacent said at least one OLED panel.

13. The luminaire of claim 12 wherein said fill panel section surrounds said OLED panel.

14. The luminaire of claim 12 wherein said fill panel section is transparent.

15. The luminaire of claim 12 wherein said fill panel section is transparent and surrounds said OLED panel such that, when the OLED panel is driven to a state of illumination, the illuminated OLED panel appears to be floating in space.

16. The luminaire of claim 1 wherein the lumen output density of said at least one OLED panel is at least about 6000 lumens/meters².

17. A luminaire for illuminating a space, comprising:
at least one panel structure having a generally planar observable surface,
at least two OLED panels having a light emitting surface, said OLED panels forming at least a portion of said panel structure and having a sufficiently high lumen output for illuminating a space, the light emitting surface of said OLED panel forming at least a portion of the generally planar observable surface of said panel structure,
a support structure for supporting said panel structure such that the generally planer observable surface of said panel structure, including the light emitting surfaces of said OLED panels, is presented to an observer located within the space to be illuminated, and
an electrical input for said OLED panels for driving said OLED panels to different states of illumination, wherein, when the OLED panels are driven to different states of illumination, the generally planar observable surface of said panel structure exhibits a low resolution light pattern thereon so as to create differential visual effects on said observable surface.

18. The luminaire of claim 17 wherein the light pattern on the generally planar observable surface of said panel structure is created at least in part by different levels of luminance on different OLED panels.

19. The luminaire of claim 17 wherein the light pattern on the generally planar observable surface of said panel structure is created at least in part by different colors of light on different OLED panels.

20. The luminaire of claim 17 wherein the light pattern on the generally planar observable surface of said panel structure is created at least in part by different levels of luminance on different OLED panels and different colors of light on different OLED panels.

21. The luminaire of claim 17 wherein the lumen output density of said at least one OLED panel is at least about 6000 lumens/meters².

22. A luminaire comprising
a light source formed by at least one OLED panel having a generally planer observable light emitting surface and a lumen output density of at least about 6000 lumens/meter²,
a support structure for supporting said light source such that, when the luminaire is turned on, the light emitting surface of said OLED panel illuminates the space,
a electrical input for driving said OLED panel to a state of illumination causing light to be emitted from the light emitting surface of said OLED panel and to produce a lumen output of at least about 2000 lumens/meter², and
said OLED light panel being characterized in that, when energized, the lighting characteristics across at least a portion of the light emitting surface thereof are non-uniform for producing for observers of the OLED light panel an observable low resolution light pattern thereon.

23. The luminaire of claim 22 wherein said OLED panel has at least two addressable pixels and wherein said electrical input drives said addressable pixels to two different states of illumination for producing an observable low resolution light pattern on the light emitting surface of said OLED panel.

24. The luminaire of claim 23 wherein the different states of illumination of the pixels of said OLED panel are characterized by different luminance levels, wherein the non-uniform lighting characteristics on the light emitting surface of said OLED panel are created by non-uniform luminance levels.

25. The luminaire of claim 23 wherein the different states of illumination of the pixels of said OLED panel are characterized by different colors of light, wherein the non-uniform lighting characteristics on the light emitting surface of said OLED panel are created by said different colors of light.

26. The luminaire of claim 23 wherein the different states of illumination of the pixels of said OLED panel are characterized by different luminance levels and different colors of light, wherein the non-uniform lighting characteristics on the light emitting surface of said OLED panel are created by said different luminance levels and different colors of light.

27. A luminaire comprising
a light source formed by at least one OLED panel having a light emitting surface and at least two addressable pixels for producing light on said light emitting surface, said OLED panel having a sufficiently high lumen output for illuminating a space,
a support structure for supporting said OLED light source in a space such that the light emitting surface thereof is visible to an observer at normal viewing angles, and
means for directly driving the at least two pixels of said OLED light source to different states of illumination so as to produce a low resolution light pattern on the light emitting surface of said OLED panel.

28. The luminaire of claim 27 wherein the different states of illumination of said pixels are different levels of luminance, and wherein the light pattern on the light emitting surface of said OLED panel is created by such difference in luminance levels.

29. The luminaire of claim 28 wherein said OLED panel has multiple pixels, the number and size of which are chosen to provide a monotonic transition in the level of luminance on the light emitting surface of the OLED panel between one area of luminance and another area of luminance, and wherein said driving means drives the different pixels so as to exhibit such transition.

30. The luminaire of claim 27 wherein said means for driving said OLED light source drives different pixels of said OLED light source so as to exhibit at least two different colors, wherein the light pattern on the light emitting surface of said OLED panel is created by areas of different colors of light.
